(19) United States
(12) Patent Application Publication
(10) Pub. No.: US 2023/0126058 A1
(43) Pub. Date: Apr. 27, 2023

(54) DIELECTRIC WINDOW FOR SUBSTRATE PROCESSING CHAMBER

(71) Applicant: LAM RESEARCH CORPORATION, Fremont, CA (US)

(72) Inventors: Maolin LONG, Santa Clara, CA (US); Michael John MARTIN, Union City, CA (US); Matthew Lowell TALLEY, Santa Clara, CA (US); Yuhou WANG, Fremont, CA (US); Alexander Miller PATERSON, San Jose, CA (US); David Robert BIGGS, Mountain View, CA (US)

(21) Appl. No.: 17/913,119

(22) PCT Filed: Mar. 22, 2021
(86) PCT No.: PCT/US2021/023420

§ 371 Date: Sep. 20, 2022

Related U.S. Application Data
(60) Provisional application No. 62/993,433, filed on Mar. 23, 2020.

(51) Int. Cl. H01J 37/32

(52) U.S. Cl. CPC H01J 37/32119; H01J 2237/334

(57) ABSTRACT

A lid assembly for a processing chamber in a substrate processing system includes a dielectric window. The dielectric window includes an upper portion having flat upper and lower surfaces. The lower surface is a plasma-facing surface of the dielectric window. A lower portion of the dielectric window is cylindrical and extends downward from the lower surface and an outer diameter of the lower portion at least one of is aligned with a gap between inner and outer coils arranged above the dielectric window and overlaps one of the inner and outer coils.

### CROSS-REFERENCE TO RELATED APPLICATIONS

This application claims the benefit of U.S. Provisional Application No. 62/993,433, filed on Mar. 23, 2020. The entire disclosure of the application referenced above is incorporated herein by reference.

### FIELD

The present disclosure relates to dielectric windows for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During manufacturing of semiconductor devices, etch processes and deposition processes may be performed within a processing chamber. Ionized gas, or plasma, can be introduced into the plasma chamber to etch (or remove) material from a substrate such as a semiconductor wafer, and to sputter or deposit material onto the substrate. Creating plasma for use in manufacturing or fabrication processes typically begins by introducing process gases into the processing chamber. The substrate is disposed in the processing chamber on a substrate support such as an electrostatic chuck or a pedestal.

The processing chamber may include transformer coupled plasma (TCP) reactor coils. A radio frequency (RF) signal, generated by a power source, is supplied to the TCP reactor coils. The TCP reactor coils are driven by a transformer coupled capacitive tuning (TCCT) match network. The TCCT match network receives the RF signal supplied by the power source and enables tuning of power provided to the TCP reactor coils. A dielectric window, constructed of a material such as ceramic, is incorporated into an upper surface of the processing chamber. The dielectric window allows the RF signal to be transmitted from the TCP reactor coils into the interior of the processing chamber. The RF signal excites gas molecules within the processing chamber to generate plasma.

### SUMMARY

A lid assembly for a processing chamber in a substrate processing system includes a dielectric window. The dielectric window includes an upper portion having flat upper and lower surfaces. The lower surface is a plasma-facing surface of the dielectric window. A lower portion of the dielectric window is cylindrical and extends downward from the lower surface and an outer diameter of the lower portion at least one of is aligned with a gap between inner and outer coils arranged above the dielectric window and overlaps one of the inner and outer coils.

In other features, the outer diameter of the lower portion is aligned with a midpoint of the gap. The dielectric window is comprised of a single integrated piece comprising the upper portion and the lower portion. The upper portion and the lower portion are separate pieces that are attached together. The lower portion is fixedly attached to the upper portion. The lower portion is removably attached to the upper portion.

In other features, the lower portion is comprised of quartz. The lower portion is comprised of alumina. The lower portion includes a plurality of gas channels configured to allow gas flow between an inner volume defined within the lower portion and an outer volume defined outside of the lower portion. The lid assembly further includes the inner and outer coils. The dielectric window has a pi-shaped cross-section.

A processing chamber in a substrate processing system includes inner and outer coils configured to generate first and second plasma fields in the processing chamber and a dielectric window. The dielectric window includes an upper portion having flat upper and lower surfaces. The lower surface is a plasma-facing surface of the dielectric window. A lower portion of the dielectric window is configured to separate the first and second plasma fields. The lower portion is cylindrical and extends downward from the lower surface. An outer diameter of the lower portion at least one of is aligned with a gap between the inner and outer coils and overlaps one of the inner and outer coils.

In other features, the outer diameter of the lower portion is aligned with a midpoint of the gap. The dielectric window is comprised of a single integrated piece comprising the upper portion and the lower portion. The upper portion and the lower portion are separate pieces that are attached together. The lower portion is removably attached to the upper portion. The lower portion is comprised of quartz. The lower portion is comprised of alumina. The lower portion includes a plurality of gas channels. The dielectric window has a pi-shaped cross-section.

A dielectric window for a processing chamber in a substrate processing system includes an upper portion having flat upper and lower surfaces. The lower surface is a plasma-facing surface of the dielectric window. A lower portion of the dielectric window is comprised of one of quartz and alumina. The lower portion is cylindrical and extends downward from the lower surface. An outer diameter of the lower portion at least one of is aligned with a gap between inner and outer coils arranged above the dielectric window and (ii) overlaps one of the inner and outer coils.

In other features, the dielectric window has a pi-shaped cross-section.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example a plasma processing system including a dielectric window in accordance with the present disclosure;

FIG. 2A is a cross-sectional side view of an example dielectric window according to the present disclosure;

FIG. 2B is an isometric view of an underside of an example dielectric window according to the present disclosure;

FIG. 2C is a bottom view of an example dielectric window according to the present disclosure; and

FIGS. 3A, 3B, and 3C show other example dielectric windows according to the present disclosure.

In the drawings, reference numbers may be reused to identify similar and/or identical elements.

### DETAILED DESCRIPTION

A dielectric window (e.g., comprising a material such as ceramic) is incorporated into an upper surface of a processing chamber in a substrate processing system. A radio frequency (RF) signal is transmitted (e.g., from transformer coupled plasma (TCP) reactor coils including an inner coil and an outer coil) into an interior volume of the processing chamber to generate plasma. The inner and outer coils generate two separate plasma fields (e.g., B fields) in the processing chamber. Typically, the dielectric window has flat upper and lower surfaces. The flat lower (plasma-facing) surface inhibits control and tunability of the distribution of the RF power in the plasma. Accordingly, tunability of center-to-edge plasma uniformity is limited and global etch tilting may occur in some applications (e.g., in high aspect ratio etching).

Systems and methods according to the principles of the present disclosure implement a dielectric window having a pi (i.e., π-shaped cross-section. For example, the dielectric window has a flat upper portion and a cylindrical lower portion extending downward from the lower surface of the upper portion. The cylindrical portion physically separates the plasma below the dielectric window into two isolated plasma zones corresponding to the inner and outer coils. Dimensions of the cylindrical portion (e.g., including, but not limited to, diameter, height, and thickness) may be selected in accordance with desired plasma characteristics such as uniformity and tunability.

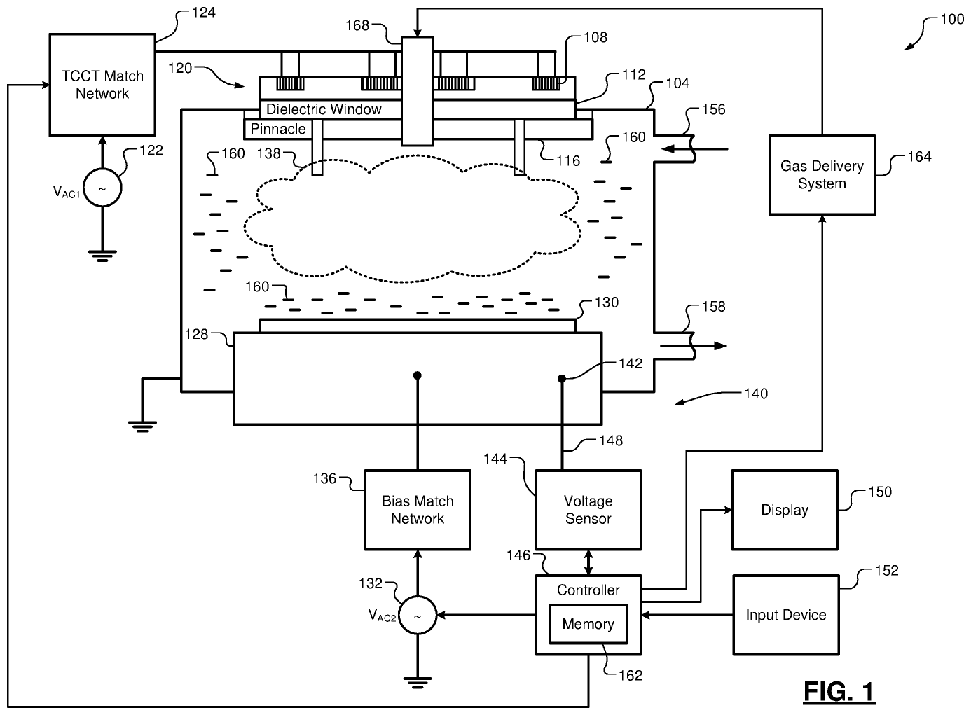

FIG. 1 shows a plasma processing system 100 that includes a processing chamber 104 and TCP reactor coils 108. A dielectric (or TCP) window 112 is arranged between the TCP reactor coils 108 and the processing chamber 104. The dielectric window 112 is arranged above a pinnacle 116 and allows transmission of RF source signals into the processing chamber 104 to generate plasma. The pinnacle 116 may correspond to an upper liner of the processing chamber 104. The pinnacle 116 may be configured to support a lid assembly 120 of the processing chamber 104 including, but not limited to, the TCP reactor coils 108 and the dielectric window 112. The dielectric window 112 according to the present disclosure has a pi (i.e., π)-shaped cross-section as described below in more detail.

A first power source 122 provides a first RF source signal to a TCCT match network 124. The TCCT (or first) match network 124 is included between the first power source 122 and the TCP reactor coils 108. The TCCT match network 124 enables tuning of power provided to the TCP reactor coils 108.

A substrate support 128 such as an electrostatic chuck, a pedestal or other suitable substrate support is arranged in the processing chamber 104. The substrate support 128 supports a substrate 130. The plasma processing system further includes a bias RF power source 132, which is connected to a bias (or second) match network 136. The second match network 136 is connected between the bias RF power source 132 and the substrate support 128. The second match network 136 matches an impedance (e.g., 50Ω) of the bias RF power source 132 to an impedance of the substrate support 128 and plasma 138 in the plasma processing chamber 104 as seen by the second matching network 136.

The plasma processing system 100 further includes a voltage control interface (VCI) 140. The VCI 40 may include a pickup device 142, a voltage sensor 144, a controller 146, and circuits arranged between the voltage sensor 144 and the controller 146. The pickup device 142 extends into the substrate support 128. The pickup device 142 is connected via a conductor 148 to the voltage sensor 144 and generates an RF voltage signal.

Operation of the voltage sensor 144 may be monitored, manually controlled, and/or controlled via the controller 146. The controller 146 may display output voltages of the channels of the voltage sensor 144 on a display 150. Although shown separate from the controller 146, the display 150 may be included in the controller 146. A system operator may provide input signals indicating (i) whether to switch between the channels, (ii) which one or more of the channels to activate, and/or (ii) which one or more of the channels to deactivate.

In operation, a gas capable of ionization flows into the plasma processing chamber 104 through the gas inlet 156 and exits the plasma processing chamber 104 through the gas outlet 158. The first RF signal is generated by the RF power source 122 and is delivered to the TCP reactor coils 108. The first RF signal radiates from the TCP reactor coils 108 through the dielectric window 112 and into the processing chamber 104. This causes the gas within the processing chamber 104 to ionize and form the plasma 138. The plasma 138 produces a sheath 160 along walls of the processing chamber 104. The plasma 138 includes electrons and positively charged ions. The electrons, being much lighter than the positively charged ions, tend to migrate more readily, generating DC bias voltages and DC sheath potentials at inner surfaces of the plasma processing chamber 104. An average DC bias voltage and a DC sheath potential at the substrate 130 affects the energy with which the positively charged ions strike the substrate 130. This energy affects processing characteristics such as rates at which etching or deposition occurs.

The controller 146 may adjust the bias RF signal generated by the RF power source 132 to change the amount of DC bias and/or a DC sheath potential at the substrate 130. The controller 146 may compare outputs of the channels of the voltage sensor 144 and/or a representative value derived based on the outputs of the channels to one or more set point values. The set point values may be predetermined and stored in a memory 162 of the controller 146. The bias RF signal may be adjusted based on differences between (i) the outputs of the voltage sensor 144 and/or the representative value and (ii) the one or more set point values. The bias RF signal passes through the second match network 136. An output provided by the second match network 136 (referred to as a matched signal) is then passed to the substrate support 128. The bias RF signal is passed to the substrate 130 through the insulator 128.

A gas delivery system 164 selectively provides one or more gas mixtures (e.g., process gas mixtures, purge gases, etc.) to the processing chamber 104 via a gas injector 168. For example, the gas delivery system 164 may include one or more sets of gas sources, valves, and flow controllers, a gas manifold, etc. (not shown) for supplying gas mixtures to the gas injector 168. The controller 146 may be configured to control the gas delivery system 164 and/or the gas injector 168 to supply the gas mixtures to the processing chamber 104.

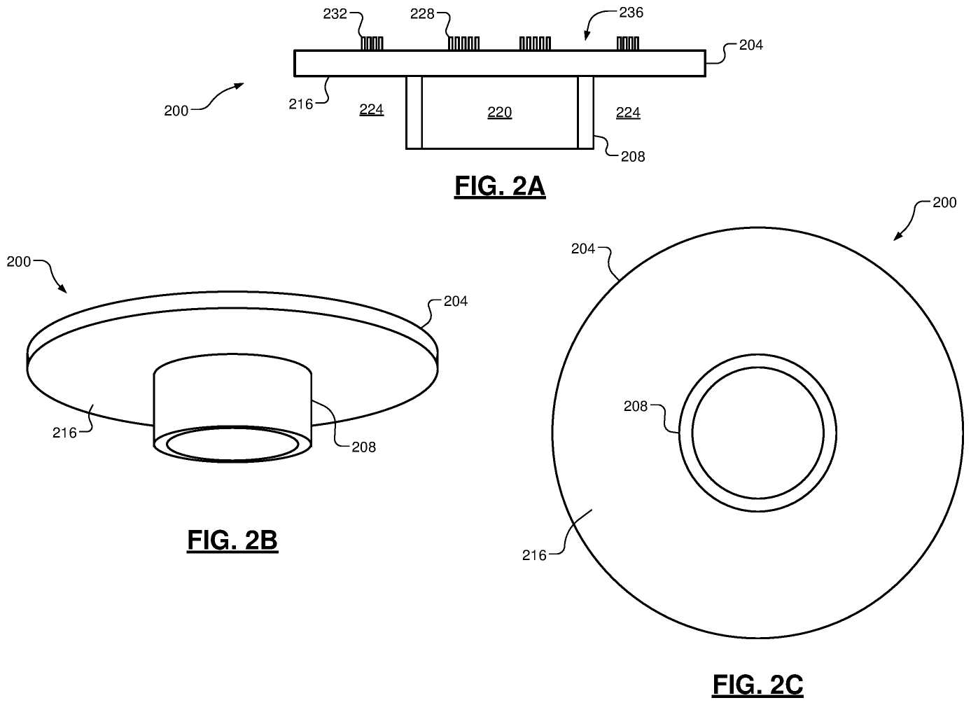

Referring now to FIGS. 2A, 2B, and 2C, and example dielectric window 200 according to the principles of the present disclosure has a pi (i.e., π)-shaped cross-section. FIG. 2A is a cross-sectional side view of the dielectric window 200. FIG. 2B is an isometric view of an underside of the dielectric window 200. FIG. 2C is a bottom view of the dielectric window 200. As shown, the dielectric window 200 has a flat upper (e.g., circular or disc-shaped) portion 204 and a cylindrical lower portion (e.g., an annular ring) 208 extending downward from a lower surface 212 of the upper portion 204.

The upper portion 204 and the lower portion 208 may comprise a same or different material. For example, the lower portion 208 may be comprised of quartz or another suitable dielectric material (e.g., high purity alumina). In some examples, the upper portion 204 and the lower portion 208 may comprise a single integrated piece. In other examples, the lower portion 208 may correspond to a separate piece that is fixedly or removably attached to the upper portion 204. For example, the lower portion 208 may be attached to the upper portion 204 using a plasma-resistant adhesive, such as an epoxy.

In examples where the lower portion 208 is removably attached to the upper portion 204, the lower portion 208 can be removed to facilitate maintenance, cleaning, and/or repair of the lower portion 208. Further, the lower portion 208 may be removed and replaced without removing the upper portion 204.

The cylindrical portion 208 physically separates plasma below the dielectric window 200 into two isolated volume 220 and 224 corresponding to respective plasma zones generated by inner and outer coils 228 and 232 (e.g., of the TCP reactor coils 108). For example, the lower portion 208 surrounds and defines the volume 220. Conversely, the volume 220 is defined outside of the lower portion 208. Dimensions (e.g., including, but not limited to, diameter, height, and thickness) of the cylindrical portion 208 may be selected in accordance with desired plasma characteristics such as uniformity and tunability.

As shown, the lower portion 208 is positioned in accordance with gap 236 between the inner coil 228 and the outer coil 232. For example, a diameter of the lower portion 208 is selected such that an outer edge (i.e., the outer diameter) of the lower portion 208 is located in the gap 236 between the inner coil 228 and the outer coil 232. The diameter of the lower portion 208 may be selected in accordance with desired performance characteristics of the plasma. In one example, diameter of the lower portion 208 is selected such that the outer diameter of the lower portion 208 is located at or near a midpoint of the gap 236 (as shown in FIG. 2A). In other examples, the diameter of the lower portion 208 is selected such that the outer diameter of the lower portion 208 is nearer to one of the inner coil 228 and the outer coil 232. In still other examples, the diameter of the lower portion 208 is selected such that the outer diameter of the lower portion 208 overlaps one of the inner coil 228 and the outer coil 232.

In examples, where the lower portion 208 is removable, the lower portion 208 may be replaced to in accordance with desired performance and tuning characteristics. For example, the lower portion 208 may be replaced with a lower portion having desired dimensions (e.g., material, height, diameter, thickness, etc.) to adjust performance characteristics. In this manner, the diameter of the inner portion 208 may be varied between 6 and 14 inches (e.g., 152 and 281 mm). The height of the inner portion 208 may be varied between 1 and 5 inches (e.g., 25 and 127 mm). The thickness of the inner portion 208 may be varied between 0.5 and 2 inches (e.g., 12 and 51 mm).

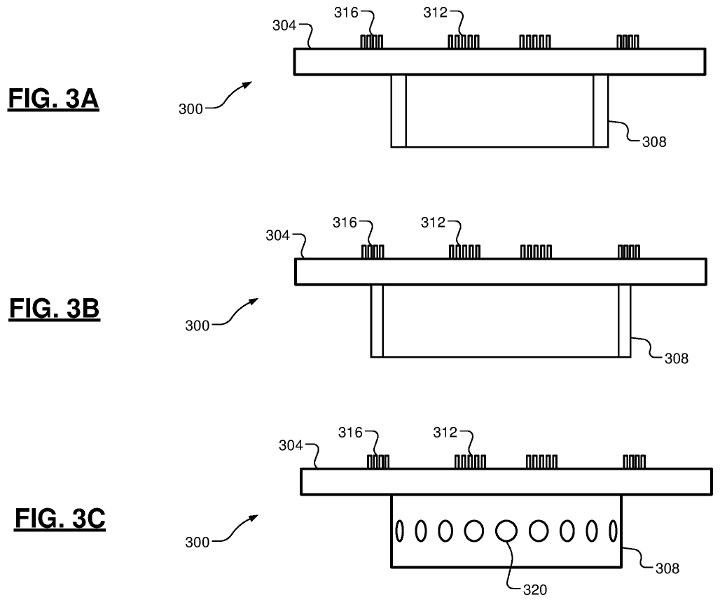

FIGS. 3A, 3B, and 3C show other examples of a dielectric window 300 including an upper portion 304 and a lower portion 308 according to the present disclosure. An inner coil 312 and an outer coil 316 are arranged on the upper portion 304. In FIG. 3A, an outer diameter of the lower portion 308 is located nearer to the outer coil 316 than to the inner coil 312. In FIG. 3B, the outer diameter of the lower portion 308 overlaps a portion of the outer coil 316.

In FIG. 3C, the lower portion 308 includes a plurality of gas channels or holes 320. The holes 320 allow gas provided to an inner volume (e.g., the inner volume 220 of FIG. 2A) of the lower portion 308 to flow into an outer volume outside (e.g., the outer volume 224 of FIG. 2A) of the lower portion 308. The holes 320 may have the same or different diameters. For example only, the holes 320 may have a diameter between 0.25 and 2 inches (e.g., 6 and 51 mm).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A lid assembly for a processing chamber in a substrate processing system, the lid assembly comprising:
a dielectric window, wherein the dielectric window includes
an upper portion having flat upper and lower surfaces, wherein the lower surface is a plasma-facing surface of the dielectric window, and
a lower portion, wherein the lower portion is cylindrical and extends downward from the lower surface, and wherein an outer diameter of the lower portion at least one of (i) is aligned with a gap between inner and outer coils arranged above the dielectric window and (ii) overlaps one of the inner and outer coils.

2. The lid assembly of claim 1, wherein the outer diameter of the lower portion is aligned with a midpoint of the gap.

3. The lid assembly of claim 1, wherein the dielectric window is comprised of a single integrated piece comprising the upper portion and the lower portion.

4. The lid assembly of claim 1, wherein the upper portion and the lower portion are separate pieces that are attached together.

5. The lid assembly of claim 4, wherein the lower portion is fixedly attached to the upper portion.

6. The lid assembly of claim 4, wherein the lower portion is removably attached to the upper portion.

7. The lid assembly of claim 1, wherein the lower portion is comprised of quartz.

8. The lid assembly of claim 1, wherein the lower portion is comprised of alumina.

9. The lid assembly of claim 1, wherein the lower portion includes a plurality of gas channels configured to allow gas flow between an inner volume defined within the lower portion and an outer volume defined outside of the lower portion.

10. The lid assembly of claim 1, further comprising the inner and outer coils.

11. The lid assembly of claim 1, wherein the dielectric window has a pi-shaped cross-section.

12. A processing chamber in a substrate processing system, comprising:
inner and outer coils configured to generate first and second plasma fields in the processing chamber; and
a dielectric window, wherein the dielectric window includes
an upper portion having flat upper and lower surfaces, wherein the lower surface is a plasma-facing surface of the dielectric window, and
a lower portion configured to separate the first and second plasma fields, wherein the lower portion is cylindrical and extends downward from the lower surface, and wherein an outer diameter of the lower portion at least one of (i) is aligned with a gap between the inner and outer coils and (ii) overlaps one of the inner and outer coils.

13. The processing chamber of claim 12, wherein the outer diameter of the lower portion is aligned with a midpoint of the gap.

14. The processing chamber of claim 12, wherein the dielectric window is comprised of a single integrated piece comprising the upper portion and the lower portion.

15. The processing chamber of claim 12, wherein the upper portion and the lower portion are separate pieces that are attached together.

16. The processing chamber of claim 15, wherein the lower portion is removably attached to the upper portion.

17. The processing chamber of claim 12, wherein the lower portion is comprised of quartz.

18. The processing chamber of claim 12, wherein the lower portion is comprised of alumina.

19. The processing chamber of claim 12, wherein the lower portion includes a plurality of gas channels.

20. The processing chamber of claim 12, wherein the dielectric window has a pi-shaped cross-section.

21. A dielectric window for a processing chamber in a substrate processing system, the dielectric window comprising:
an upper portion having flat upper and lower surfaces, wherein the lower surface is a plasma-facing surface of the dielectric window, and
a lower portion comprised of one of quartz and alumina, wherein the lower portion is cylindrical and extends downward from the lower surface, and wherein an outer diameter of the lower portion at least one of (i) is aligned with a gap between inner and outer coils arranged above the dielectric window and (ii) overlaps one of the inner and outer coils.

22. A dielectric window of claim 21, wherein the dielectric window has a pi-shaped cross-section.
